(19) United States
(12) Patent Application Publication
(10) Pub. No.: US 2015/0179233 A1
(43) Pub. Date: Jun. 25, 2015

(54) SEMICONDUCTOR SYSTEM AND POWER SOURCE CHIP

(71) Applicant: KABUSHIKI KAISHA TOSHIBA, Tokyo (JP)

(72) Inventor: Naoki KIMURA, Ebina (JP)

(73) Assignee: KABUSHIKI KAISHA TOSHIBA, Tokyo (JP)

(21) Appl. No.: 14/258,917

(22) Filed: Apr. 22, 2014

(30) Foreign Application Priority Data
Dec. 25, 2013 (JP) 2013-266581

(51) Int. Cl. G11C 5/14

(52) U.S. Cl. CPC G11C 5/147

(57) ABSTRACT

A semiconductor system includes a semiconductor memory unit configured to store data, a controller configured to control the semiconductor memory unit and operable in one of first and second modes, and a power source unit configured to supply power of varying levels to the controller depending on whether the controller is operating in the first mode or the second mode.

### CROSS-REFERENCE TO RELATED APPLICATION

This application is based upon and claims the benefit of priority from Japanese Patent Application No. 2013-266581, filed Dec. 25, 2013, the entire contents of which are incorporated herein by reference.

### FIELD

Embodiments described herein relate generally to a semiconductor system and a power source chip of the semiconductor system.

### BACKGROUND

Generally, a semiconductor system includes one or more semiconductor chips and a power source chip that supplies power to the one or more semiconductor chips. One type of the semiconductor system includes a power source chip having a voltage switching control circuit. The reduction of power consumption is desirable for such a semiconductor system.

### DESCRIPTION OF THE DRAWINGS

FIG. 1 is a block diagram exemplifying a semiconductor system according to a first embodiment.

FIG. 2 is a block diagram exemplifying a peripheral circuit of a power source chip according to the first embodiment.

FIG. 3 is a block diagram exemplifying an internal configuration of the power source chip according to the first embodiment.

FIG. 4 is a graph exemplifying switching of an output voltage of the power source chip according to the first embodiment.

FIG. 5 is a flowchart exemplifying the flow of switching of the output voltage of the power source chip according to the first embodiment.

FIG. 6 is a cross-sectional view of a semiconductor system according to a second embodiment.

FIG. 7 is a block diagram exemplifying the semiconductor system according to the second embodiment.

### DETAILED DESCRIPTION

According to an embodiment, there are provided a semiconductor system, a power source constituting component, and a semiconductor component which may reduce power consumption.

In general, according to one embodiment, a semiconductor system includes a semiconductor memory unit configured to store data, a controller configured to control the semiconductor memory unit and operable in one of first and second modes, and a power source unit configured to supply power of varying levels to the controller depending on whether the controller is operating in the first mode or the second mode.

Hereinafter, embodiments are explained by reference to drawings.

In this disclosure, with respect to some elements, a plurality of expressions is used for expressing one element. However, these expressions are merely examples, and it is not denied that each of the above-described elements is expressed by other expressions. Further, elements which are not expressed by a plurality of expressions may be also expressed using different expressions.

### First Embodiment

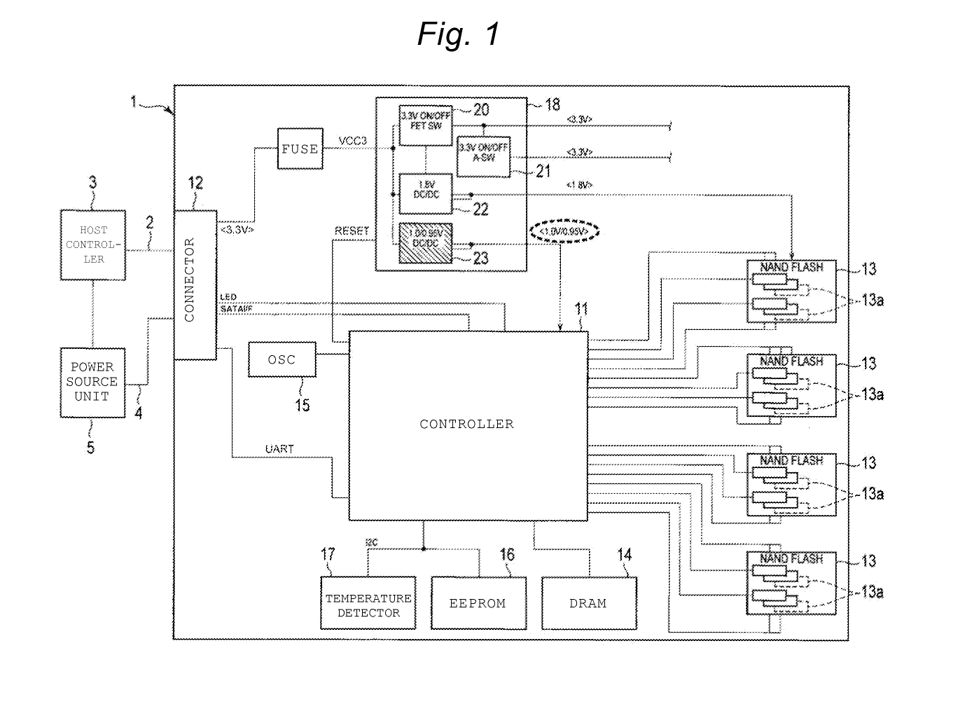

FIG. 1 is a block diagram showing one example of a semiconductor device 1 according to a first embodiment. The semiconductor device 1 may be an example of “semiconductor system”. The semiconductor device 1 is, for example, a semiconductor storage device (memory system), and one example of the semiconductor device 1 is an SSD (Solid State Drive). However, the semiconductor device 1 is not limited to the SSD.

The semiconductor device 1 is electrically connected to a host controller 3 through an interface 2. The host controller 3 executes a data access control on the semiconductor device 1. For example, the host controller 3 transmits a write request, a read request, and an erasing request to the semiconductor device 1, thus executing writing, reading, and erasing of data with respect to the semiconductor device 1. The semiconductor device 1 is also electrically connected to a power source unit 5 (power source circuit) of a host device through a power source line 4. The power source unit 5 supplies various power sources to be used in the semiconductor device 1.

As shown in FIG. 1, the semiconductor device 1 includes: a controller (controller chip, storage controller) 11; a connector 12; a semiconductor memory 13; a DRAM (Dynamic Random Access Memory) 14; an oscillator (OSC) 15; an electrically erasable and programmable ROM (EEPROM) 16; a temperature sensor 17; and a power source unit 18.

The controller 11 is connected to the host controller 3 through the connector 12 and the interface 2. The interface 2 is for example, Serial Advanced Technology Attachment (SATA), Peripheral Component Interconnect Express (PCIe), Serial Attached SCSI (SAS), Universal Serial Bus (USB), or the like. However, the interface 2 is not limited to such interfaces.

The controller 11 is one example of “semiconductor chip.” The controller 11 controls an operation of the semiconductor device 1 in a comprehensive manner in response to an instruction from the host controller 3. The controller 11 executes an access control to the semiconductor memory 13. That is, the controller 11 controls writing, holding, reading, and erasing of data with respect to the semiconductor memory 13.

The semiconductor memory 13 is one example of a non-volatile memory, and is a NAND-type flash memory, for example. The semiconductor memory 13 includes a plurality of NAND memory chips 13a, for example. The DRAM 14 is one example of a volatile memory.

The semiconductor device 1 has a normal mode (active mode, first mode, first power consumption mode), and a low power consumption mode where power consumption of the semiconductor device 1 is smaller compared to the normal mode (standby mode, second mode, second power consumption mode). “Mode” indicates an operational state.

The normal mode is a state in which a data transfer operation is possible between the host controller 3 and the semiconductor device 1. That is, the semiconductor device 1 performs writing of data, reading of data, and erasing of data with respect to the semiconductor memory 13 in response to a request from the host controller 3 in the normal mode.

In this normal mode, the controller 11 of the semiconductor device 1 executes writing of data, reading of data, and erasing of data with respect to the semiconductor memory 13 in response to an instruction from the host controller 3, and hence a processing load is relatively large. In this normal mode, power consumption (operating current) of the controller 11 is relatively large, and hence a change in the load (change in power consumption) is also large.

On the other hand, the low power consumption mode is a standby state in which the data transfer operation is stopped between the host controller 3 and the semiconductor device 1. That is, in the low power consumption mode, an instruction from the host controller 3 is stopped so that writing of data, reading of data, and erasing of data are not performed with respect to the semiconductor memory 13.

In this low power consumption mode, the operation of the controller 11 is less active than the operation of the controller 11 in the normal mode. Accordingly, in the low power consumption mode, power consumption (operating current) of the controller 11 is relatively small so that a change in the load (change in power consumption) is also small.

Statuses of the semiconductor device 1, which is, for example, an SSD drive, include an active mode, an idle mode, a standby mode, and a sleep mode.

The active mode is the above-described normal mode, and is a state in which writing and reading are performed. The idle mode is a state in which writing and reading are on standby.

The standby mode is a state in which operations other than communication (for example, communication of SATA or PCIe) between the controller 11 and the host controller 3 is stopped.

That is, an access to the semiconductor memory 13 and the DRAM 14 is stopped, and the supply of power from the power source unit 18 is also stopped when necessary.

The sleep mode is a state in which the communication between the controller 11 and the host controller 3 is also stopped unlike the above-described standby state, so that all operations of the semiconductor device 1 are stopped.

Although the above-described standby mode and sleep mode respectively correspond to the low power consumption mode according to this embodiment as an example, the low power consumption mode is not limited to these modes. Further, from a view point of a status of the interface, the power consumption mode according to this embodiment is a Slumber mode of SATA standard or a “L1.OFF” mode of PCIe standard, for example. However, the low power consumption mode is not limited to these modes.

The oscillator 15 supplies an operational signal of a predetermined frequency to the controller 11. The EEPROM 16 stores a control program and the like as fixed information. The EEPROM 16 is one example of the non-volatile memory. The temperature sensor 17 detects a temperature in the semiconductor device 1, and notifies the controller 11 of the detected temperature.

The power source unit 18 is electrically connected to the power source unit 5 of the host device through the connector 12 and the power source line 4. A power necessary for the semiconductor device 1 is supplied from the power source unit 5 of the host device through the power source unit 18. The power source unit 18 is electrically connected to the controller 11, the semiconductor memory 13, and the DRAM 14. The power source unit 18 supplies power to the controller 11, the semiconductor memory 13, and the DRAM 14.

As shown in FIG. 1, the power source unit 18 includes, for example, two switches 20, 21 and two power source chips 22, 23. The power source chips 22, 23 are respectively, for example, formed of a power source IC of a DC-DC converter type. The power source chip 22 is electrically connected to the semiconductor memory 13, for example, and supplies power having a voltage of 1.8V to the semiconductor memory 13.

The power source chip 23 is one example of “power source unit”. The power source chip 23 is electrically connected to the controller 11, and may selectively supply power having a plurality of reference voltages to the controller 11. To be more specific, the power source chip 23 may selectively supply power having a first voltage V1 (first reference voltage) and power having a second voltage V2 (second reference voltage) that is lower than the first voltage V1, to the controller 11. One example of the first voltage V1 is 1.0 V. One example of the second voltage V2 is 0.95 V.

As described in detail below, the power source chip 23 supplies power having the first voltage V1 to the controller 11 in the normal mode, and supplies power having the second voltage V2 in the low power consumption mode. The value of the first voltage V1 and the value of the second voltage V2 are not limited to the above-described examples. Further, the power source unit 18 may include, for example, one power source chip which integrally includes functions of the above-described switches 20, 21 and power source chips 22, 23.

Next, the power source chip 23 is explained in detail.

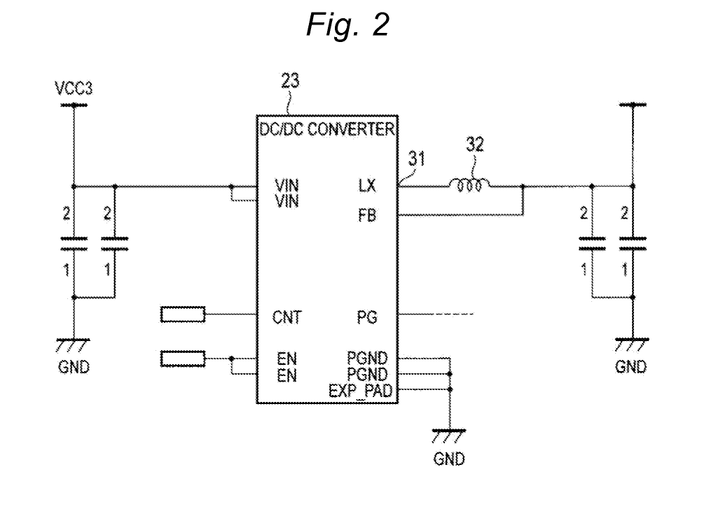

The power source chip 23 is one example of “semiconductor component” or “package”. FIG. 2 shows one example of a peripheral circuit of the power source chip 23. The power source chip 23 includes an output terminal 31 from which power is supplied to the controller 11. Power is output from the output terminal 31 in the form of a pulse having a rectangular waveform, for example. An inductor 32 is connected to the output terminal 31. The inductor 32 rectifies an output from the output terminal 31.

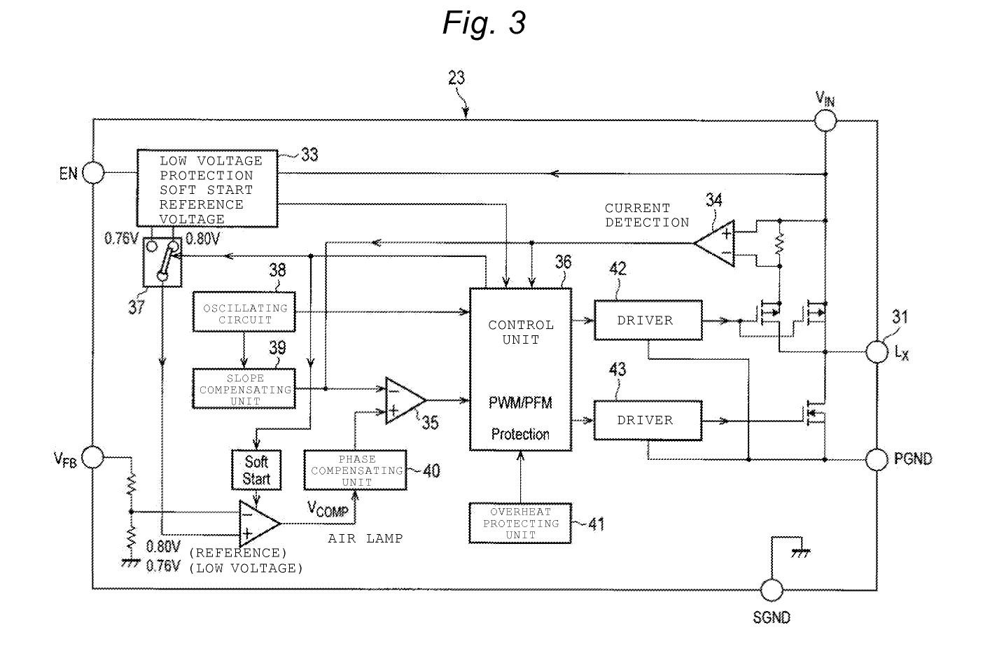

FIG. 3 shows one example of the internal configuration of the power source chip 23. The power source chip 23 includes, in addition to the above-described output terminal 31: a setting unit 33 (voltage setting unit); a current detecting unit 34; a PWM comparator 35; a control unit 36 (control logic unit); a switching unit 37; an oscillating circuit unit 38; a slope compensating unit 39; a phase compensating unit 40; an overheat protecting unit 41; and drivers 42, 43.

The setting unit 33 may set a plurality of (for example, two) output voltage values. To be more specific, the setting unit 33 may set a first set voltage (for example, 0.80 V) corresponding to the first voltage V1 and a second set voltage (for example, 0.76V) corresponding to the second voltage V2. By switching the first set voltage and the second set voltage, power having the first voltage V1 or power having the second voltage V2 is output from the output terminal 31.

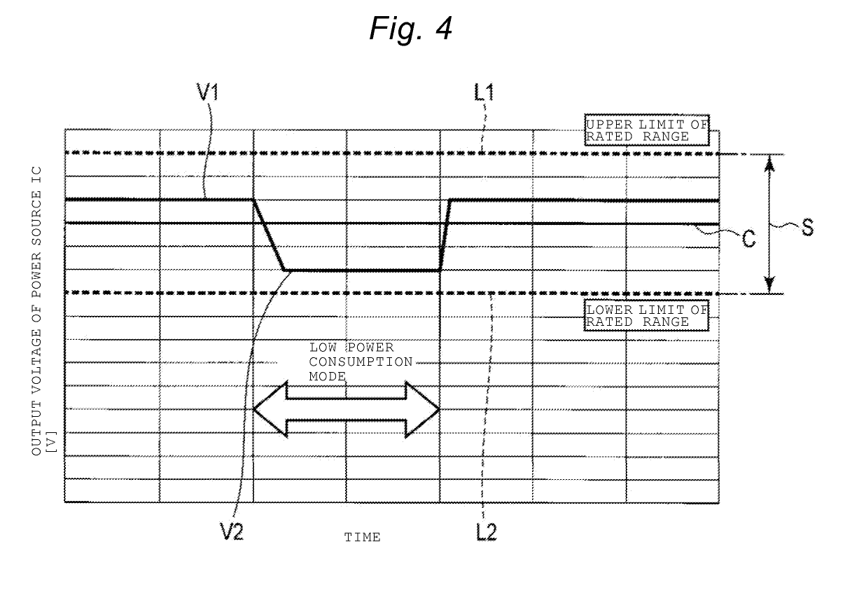

FIG. 4 shows a rated range (specification) with respect to a power source voltage of the controller 11. The rated range S has an upper limit L1, a lower limit L2, and a center value C, which is a central value between the upper limit L1 and the lower limit L2. The first voltage V1 of the power source chip 23 is set to the central value C or more (that is, equal to or higher than the central value C) within the rated range S of the controller 11. In this embodiment, the first voltage V1 is set to a value higher than the central value C of the rated range S of the controller 11.

On the other hand, the second voltage V2 is set to a value lower than the central value C within the rated range S of the controller 11. In this embodiment, the second voltage V2 is set to a value closer to the lower limit L2 than to the central value C of the rated range S of the controller 11. That is, the second voltage V2 is set lower than a value at the center between the central value C and the lower limit L2.

The current detecting unit 34 is one example of a “detecting unit”, and detects a mode shift when the semiconductor device 1 is shifted to the low power consumption mode from the normal mode. To be more specific, the current detecting unit 34 monitors a change in an electric current output to the controller 11 from the output terminal 31. The current detecting unit 34 detects the mode shift from the normal mode to the low power consumption mode when a value of an electric current output to the controller 11 from the output terminal 31 becomes lower than a predetermined value.

That is, the power source chip 23 incorporates therein the detecting unit which detects the mode shift to the low power consumption mode by monitoring a change in an electric current output to the controller 11 from the output terminal 31.

The current detecting unit 34 also detects a mode shift when the semiconductor device 1 returns to the normal mode from the low power consumption mode. To be more specific, the current detecting unit 34 monitors a change in an electric current output to the controller 11 from the output terminal 31, and detects the mode shift to the normal mode from the low power consumption mode when the value of the monitored electric current becomes higher than a predetermined value.

The current detecting unit 34, upon detection of the mode shift to the low power consumption mode or upon detection of the mode shift to the normal mode, transmits a signal indicative of the mode shift to the control unit 36. The control unit 36 operates the power source chip 23 with a pulse width modulation method (PWM) when the semiconductor device 1 is in the normal mode. On the other hand, the control unit 36 operates the power source chip 23 with a pulse frequency modulation method (PFM) for enhancing output efficiency when the semiconductor device 1 is in the low power consumption mode.

Power output from the output terminal 31 to the controller 11 has the first voltage V1 during the normal mode. The switching unit 37 switches a reference voltage output from the output terminal 31 from the first voltage V1 to the second voltage V2 when the current detecting unit 34 detects the mode shift to the above-described low power consumption mode. In this switching operation, the reference voltage maybe smoothly switched such that a spike-shaped change in voltage is not generated by providing a plurality of voltage values in a stepwise manner between the first voltage V1 and the second voltage V2.

Further, the switching unit 37 causes a voltage of power output from the output terminal 31 to be switched from the second voltage V2 to the first voltage V1 when the current detecting unit 34 detects the mode shift to the normal mode. Also in this switching, the voltage may be smoothly switched such that a spike-like change in voltage is not generated by providing a plurality of voltage values in a stepwise manner between the second voltage V2 and the first voltage V1.

Next, the flow of the mode shift of the semiconductor device 1 from the normal mode to the low power consumption mode is explained.

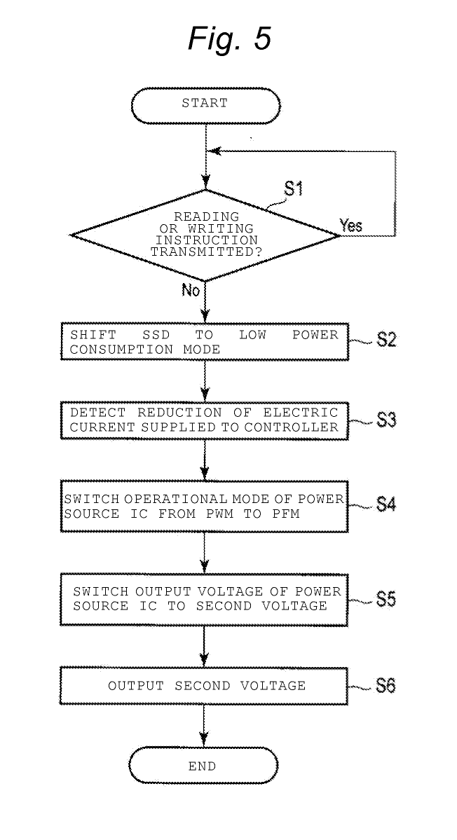

FIG. 5 shows the flow of switching of a voltage value of power output from the power source chip 23. As described previously, when the semiconductor device 1 is in the normal mode, the controller 11 receives an instruction from the host controller 3 and performs writing and reading to and from the semiconductor memory 13.

The semiconductor device 1 is operated in the normal mode when a writing or reading instruction is transmitted from the host controller 3 (step S1). Then, when the instruction from the host controller 3 is stopped for a period longer than a predetermined time, the semiconductor device 1 shifts its operation mode to a standby mode, which is the low power consumption mode in this embodiment, via an idle mode, for example (step S2). The semiconductor device 1 may shift to the low power consumption mode based on an instruction from the host controller 3.

When the semiconductor device 1 shifts to the low power consumption mode, a processing load (power consumption) of the controller 11 becomes small, and hence a value of a supplied electric current decreases. The current detecting unit 34 of the power source chip 23 detects the mode shift of the semiconductor device 1 to the low power consumption mode when a value of an electric current output to the controller 11 becomes lower than a predetermined value (step S3). The current detecting unit 34 transmits, upon detection of the mode shift of the semiconductor device 1 to the low power consumption mode, a signal indicative of the detection of the mode shift to the control unit 36.

The control unit 36, upon reception of the signal from the current detecting unit 34, switches an operational mode of the power source chip 23 from a pulse width modulation mode (PWM) to a pulse frequency modulation mode (PFM) (step S4). The control unit 36, upon switching of the operation mode of the power source chip 23 from the PWM to the PFM, transmits a signal for switching an output voltage of power to be output from the output unit 11, to the switching unit 37. In other words, the power source chip 23 according to this embodiment detects the mode shift of the semiconductor device 1 to a low power consumption mode based on switching of the operational mode of the power source chip 23 from the PWM to the PFM and transmits a signal indicative of the detection of the mode shift to the switching unit 37. That is, it is safe to say that the control unit 36 is an example of the determining unit which determines the mode shift of the semiconductor device 1 to a low power consumption mode.

Upon receiving the above-described signal from the control unit 36, the switching unit 37 switches a reference voltage output from the output terminal 31 from the first voltage V1 to the second voltage V2 (step S5). As a result, the output terminal 31 outputs the second voltage V2 to the controller 11 (step S6).

The mode shift of the semiconductor device 1 from the low power consumption mode to the normal mode maybe performed in accordance with the substantially same steps. That is, the current detecting unit 34 detects a change in a value of electric current supplied to the controller 11, and detects the mode shift of the semiconductor device 1 to the normal mode when a value of the electric current becomes higher than a predetermined value.

Upon detection of the mode shift of the semiconductor device 1 to the normal mode, the power source chip 23 switches an operational mode thereof from PFM to the PWM and, at the same time, readily switches an output voltage to the controller 11 from the second voltage V2 to the first voltage V1 thus preventing the output voltage from going out of the rated range S of the controller 11. Further, at the time of turning on the semiconductor device 1 or at the time of returning the semiconductor device 1 from a stopped state, the power source chip 23 is set to output power having the first voltage V1.

According to the above-described configuration, the power consumption of the semiconductor device 1 can be reduced.

An output voltage of the power source chip conventionally has been set to a central value between an upper limit and a lower limit of a rated range of a semiconductor device such that the output voltage does not go out of the rated range of the semiconductor chip even when a change in a processing load due to an operation of the semiconductor device such as writing or reading is large.

In this case, however, even when there is a margin in a rated range of the semiconductor chip in a state in which a change in a processing load is small such as a low power consumption mode, an output voltage is be changed. Hence, the power consumption of the semiconductor device 1 cannot be reduced.

As one method for dealing with such a situation, it may be possible to change a value of voltage by forcibly switching a monitor voltage of the power source chip using an external circuit. In this case, however, a spike-like change in voltage may be generated at the time of switching an output voltage and thus maybe undesirable for a power source circuit. Further, when the external circuit is used, an additional wiring is required, thus pushing up a manufacturing cost of the semiconductor device.

As another method for dealing with the above-described situation, an output voltage may be switched by transmitting a control signal to the power source chip from the controller. In this case, however, it is necessary to provide a signal line which connects the controller and the power source chip to each other and a program for transmitting the control signal from the controller, thus pushing up a manufacturing cost of the semiconductor device.

In view of the above, in the semiconductor device 1 according to this embodiment, the power source chip 23 may set a plurality of output voltages, wherein power having the first voltage V1 is output to the controller 11 at the time of operating the semiconductor device 1 in the normal mode, and the mode shift to the low power consumption mode is detected so that a value of voltage output to the controller 11 is switched from the first voltage V1 to the second voltage V2 that is lower than the first voltage V1. In other words, the power source chip 23 according to this embodiment detects an operational state of the controller 11 by itself and autonomously switches the output voltage. That is, the power source chip 23 may perform all operations necessary for switching an output voltage in the power source chip 23.

According to such a configuration, in the normal mode where a change in a processing load is large, power having the first voltage V1 is output to the controller 11 thus enabling the controller 11 and the semiconductor device 1 to perform a stable operation. When the semiconductor device 1 turns into a low power consumption mode where a change in the processing load is small, an output voltage is switched to the second voltage V2 that is smaller than the first voltage V1, and hence, the power consumption of the semiconductor device 1 may be reduced.

Further, according to this embodiment, the power source chip 23 includes the detecting unit which detects a change in a value of an electric current from the output terminal 31 to detect the mode shift of the semiconductor device 1 to a low power consumption mode therein. According to such a configuration, it is unnecessary to provide an external circuit for switching an output voltage, a signal line which connects the controller and the power source chip, a program of the controller for instructing the power source chip 23 to switch an output voltage, or the like. Thus, a manufacturing cost of the semiconductor device 1 can be reduced.

Further, the controller 11 is one of units which consume large amount of power in the semiconductor device 1. Accordingly, if the power consumption of the controller 11 can be reduced, the power consumption of the entire semiconductor device 1 can be reduced effectively.

In this embodiment, the power source chip 23 detects the mode shift of the semiconductor device 1 to the low power consumption mode by detecting a change in a value of an electric current output to the controller 11 from the power source chip 23. According to such a configuration, even in the semiconductor device 1 which is required to perform a high speed operation such as an SSD, for example, an output voltage of power supplied to the power source chip 23 may be switched following the mode shift from the normal mode to the low power consumption mode and the return from the low power consumption mode to the normal mode at a high speed.

In this embodiment, the first voltage V1 is set to a value equal to or greater than the central value C between the upper limit L1 and the lower limit L2 of the rated range S of a power source voltage of the controller 11, and the second voltage V2 is set to a value lower than the central value C. That is, in the normal mode where a change in a processing load is large, by setting the first voltage V1 to a value equal to or greater than the central value C of the rated range S, a sufficient margin may be ensured on the lower limit L2 side of the rated range S. On the other hand, in the low power consumption mode where a change in the processing load is small, by switching the first voltage V1 to the second voltage V2 which is smaller than the central value C of the rated range S, the power consumption may be effectively reduced.

In general, with respect to a rated range of a semiconductor chip such as the controller 11, an allowable voltage range which goes beyond the upper limit of the rated range is larger than an allowable voltage range which goes beyond the lower limit. Accordingly, in this embodiment, while aiming at the reduction of the power consumption in a low power consumption mode, the first voltage V1 in the normal mode is set to a value higher than the central value C of the rated range S. According to such a setting, it is possible to enhance stability of an operation of the semiconductor device 1 in the normal mode compared to a case where an output voltage is set to the central value C of the rated range S, while lowering the power consumption of the semiconductor device.

In this embodiment, the second voltage V2 is set closer to the lower limit L2 than to the central value C of the rated range S of the controller 11. According to such a setting, the power consumption in the low power consumption mode may be effectively reduced, and hence the power consumption of the semiconductor device 1 may be further effectively reduced.

In this embodiment, the power source chip 23 includes the control unit 36 which switches an operational mode of the power source chip 23 from the PWM to PFM when the current detecting unit 34 detects the mode shift to the low power consumption mode. That is, the power source chip 23 according to this embodiment has, for enhancing output efficiency, the control unit 36 which switches an operational mode of the power source chip 23 from the PWM to PFM when an operating current becomes small.

Then, the power source chip 23 operates the switching unit 37 based on a signal from the control unit 36, and switches the setting of an output voltage to the second voltage V2 from the first voltage V1. That is, due to such a configuration, it is possible to transmit a signal to the switching unit 37 from the control unit 36 by making use of a switching operation in an operational mode of the power source chip 23 for enhancing output efficiency. Accordingly, it is unnecessary to provide the current detecting unit 34 and the control unit 36 dedicated to the switching of an output voltage, and hence a manufacturing cost of the power source chip 23 may be reduced.

### Second Embodiment

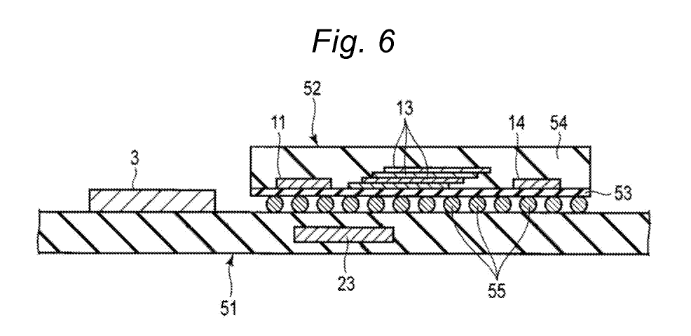

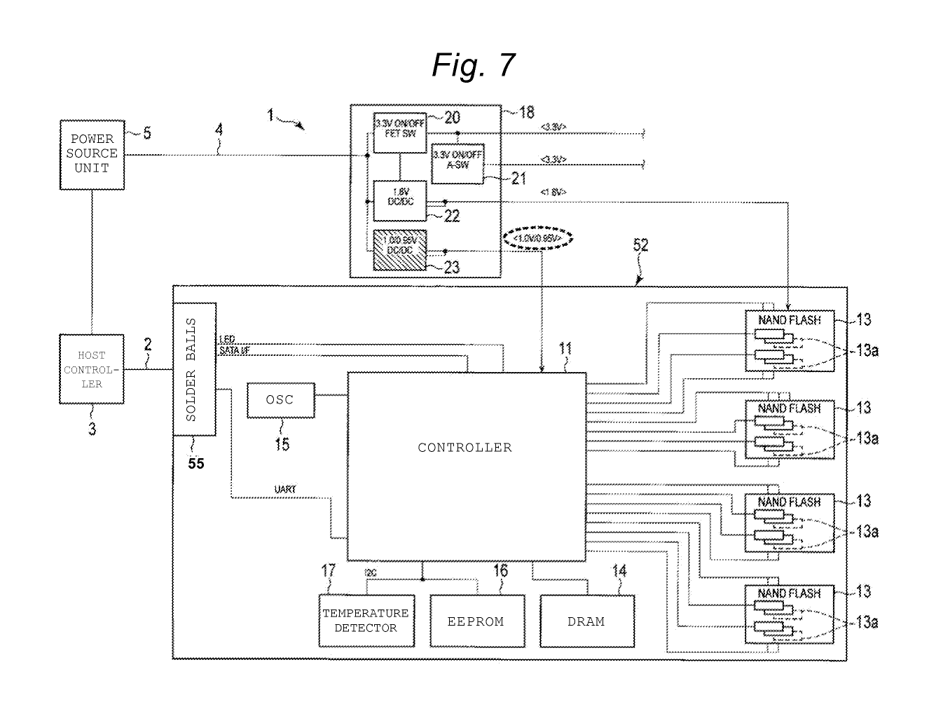

Next, a semiconductor device 1 according to a second embodiment is explained by reference to FIG. 6 and FIG. 7. Elements having identical or similar configuration or function to the elements of the first embodiment are shown by the same symbols, and the explanation of these units is omitted. Further, elements of this embodiment other than the elements described below are equal to the corresponding elements of the first embodiment.

FIG. 6 is a cross-sectional view of the semiconductor device 1 according to the second embodiment. FIG. 7 is a block diagram showing one example of the semiconductor device 1 according to this embodiment. The semiconductor device 1 (semiconductor system) according to this embodiment includes a printed circuit board 51, a semiconductor package 52, and the power source chip 23.

The semiconductor package 52 is a so-called BGA-SSD (Ball Grid Array—Solid State Drive) , and is a package of a BGA type. In this embodiment, the controller 11, the semiconductor memory 13, and the DRAM 14 are formed as one semiconductor package 52.

To explain in detail, the semiconductor package 52 includes a substrate (package substrate) 53. The controller 11, the semiconductor memory 13, the DRAM 14, the oscillator 15, the EEPROM 16, and the temperature sensor 17 are electrically connected to the substrate 53, and are commonly sealed by a sealing member 54. A plurality of solder balls 55 which constitute connection terminals are mounted on the substrate 53 so as to be connected to pads formed on the printed circuit board 51.

On the other hand, the power source chip 23 is built in the printed circuit board 51 separately from the semiconductor package 52. As shown in FIG. 6, the power source chip 23 is incorporated into the printed circuit board 51, for example. The power source chip 23 may be mounted on a surface of the printed circuit board 51. The power source chip 23 may be built in the inside of the semiconductor package 52.

According to such a constitution, when the semiconductor device 1 turns into a low power consumption mode where a change in a processing load is small, the setting of an output voltage of power to be supplied to the controller 11 is switched to the second voltage V2 that is smaller than the first voltage V1 from the first voltage V1. Accordingly, in the same manner as in the first embodiment, the power consumption of the semiconductor device 1 may be reduced.

Further, according to this embodiment, in the same manner as in the first embodiment, a signal line for switching a voltage is unnecessary between the power source chip 23 and the controller 11. Accordingly, when the power source chip 23 is provided outside of the semiconductor package 52, the solder balls 55 on the semiconductor package 52 which constitute a part of the signal line maybe omitted. Further, a manufacturing cost of the semiconductor device 1 may be reduced, and flexibility in layout of the semiconductor package 52 may be increased and the semiconductor package may be miniaturized.

While certain embodiments have been described, these embodiments have been presented by way of example only, and are not intended to limit the scope of the inventions. Indeed, the novel embodiments described herein may be embodied in a variety of other forms. Furthermore, various omissions, substitutions and changes in the form of the embodiments described herein maybe made without departing from the spirit of the inventions. The accompanying claims and their equivalents are intended to cover such forms or modifications as would fall within the scope and spirit of the inventions.

For example, the destination to which power is supplied from the power source chip 23 capable of changing the output voltage is not limited to the controller 11, and the destination may the DRAM 14 or other semiconductor chips. Further, the setting of the first voltage V1 and the second voltage V2 is not limited to the above-described values.

What is claimed is:

1. A semiconductor system comprising:
a semiconductor memory unit configured to store data;
a controller configured to control the semiconductor memory unit and operable in one of first and second modes; and
a power source unit configured to supply power of varying levels to the controller depending on whether the controller is operating in the first mode or the second mode.

2. The semiconductor system according to claim 1, wherein
the controller is configured to carry out data transfer with the semiconductor memory unit when the controller is operating in the first mode, and to not carry out the data transfer with the semiconductor memory unit when the controller is operating in the second mode.

3. The semiconductor system according to claim 2, wherein
the power source unit is configured to supply power having a first voltage when the controller is operating in the first mode, and supply power having a second voltage that is lower than the first voltage when the controller is operating in the second mode.

4. The semiconductor system according to claim 1, wherein
the power source unit is further configured to determine whether the controller is operating in the first mode or the second mode, and supply the power of varying levels to the controller depending on the determination result of whether the controller is operating in the first mode or the second mode

5. The semiconductor system according to claim 4, wherein
the power source unit includes a detecting unit configured to detect a level of current supplied to the controller, and the power source unit is configured to determine whether the controller is in the first mode or in the second mode based on the detected level.

6. The semiconductor system according to claim 5, wherein
the power source unit is configured to determine that the controller is operating in the first mode when the detected level is higher than a predetermined level, and that the controller is operating in the second mode when the detected level is lower than the predetermined level.

7. The semiconductor system according to claim 1, wherein the power source unit includes,
a control unit configured to generate a first signal when the controller is operating in the first mode, and a second signal when the controller is operating in the second mode, and
a setting unit configured to set a voltage of the power to be supplied to the controller based on whether the first signal or the second signal is received.

8. The semiconductor system according to claim 7, wherein the setting unit is configured to set the voltage of the power to be supplied to the controller to a first voltage when the first signal is received, and to a second voltage which is lower than the first voltage, when the second signal is received.

9. The semiconductor system according to claim 8, wherein the first signal is a pulse width modulation signal, and the second signal is a pulse frequency modulation signal.

10. A power source chip comprising:
an output unit configured to supply power to a semiconductor chip;
a control unit configured to determine whether the semiconductor chip is operating in a first mode or in a second mode that is different from the first mode,
a setting unit configured to set a voltage of the power to be supplied to the semiconductor chip to a first voltage when the control unit determines that the semiconductor chip is operating in the first mode, and to a second voltage that is lower than the first voltage when the control unit determines that the semiconductor chip is operating in the second mode.

11. The power source chip according to claim 10, wherein the control unit is configured to determine whether the semiconductor chip is operating in the first mode or in the second mode based on a level of current that the output unit supplies to the semiconductor chip.

12. The power source chip according to claim 11, further comprising:
a detecting unit configured to detect the level of current that the output unit supplies to the semiconductor chip, wherein
the control unit is configured to determine whether the semiconductor chip is operating in the first mode or in the second mode based on the detected level.

13. The power source chip according to claim 12, wherein the control unit is configured to determine that the semiconductor chip is operating in the first mode when the detected level is higher than a predetermined level, and that the semiconductor chip is operating in the second mode when the detected level is lower than the predetermined level.

14. The power source chip according to claim 10, wherein
the control unit is further configured to generate a first signal when the control unit determines that the semiconductor chip is operating in the first mode, and a second signal when the control unit determines that the semiconductor chip is operating in the second mode, and
the setting unit is configured to set the voltage of the power to be supplied to the semiconductor chip to the first voltage when the setting unit receives the first signal and to the second voltage when the setting unit receives the second signal.

15. A method of operating a semiconductor system including a semiconductor memory unit, and a controller configured to control the semiconductor memory unit and operable in one of first and second modes, the method comprising:
determining whether the controller is operating in the first mode or the second mode; and
supplying power of varying levels to the controller depending on whether the controller is determined to be operating in the first mode or the second mode.

16. The method according to claim 15, wherein
data transfer is carried out between the semiconductor memory unit and the controller when the controller is operating in the first mode, and the data transfer is not carried out when the controller is operating in the second mode.

17. The method according to claim 15, wherein
a first voltage is supplied to the controller when the controller is determined to be operating in the first mode, and a second voltage that is lower than the first voltage is supplied to the controller when the controller is determined to be operating in the second mode.

18. The method according to claim 15, further comprising:
detecting a level of current value supplied to the controller, wherein
whether the controller is operating in the first mode or the second mode is determined based on the detected level.

19. The method according to claim 18, wherein
the controller is determined to be operating in the first mode when the detected level is higher than a predetermined level, and in the second mode when the detected level is lower than the predetermined level.
